(19) United States
(12) Patent Application Publication
(10) Pub. No.: US 2025/0098113 A1
(43) Pub. Date: Mar. 20, 2025

(54) COOLANT DISTRIBUTION DEVICE

(71) Applicant: LITE-ON TECHNOLOGY CORPORATION, TAIPEI CITY (TW)

(72) Inventors: SHI-BIN WANG, TAIPEI CITY (TW); PIN-YING TSENG, TAINAN CITY (TW); WEN-CHI CHEN, TAIPEI CITY (TW); SHU-HUA MAU, TAOYUAN CITY (TW)

(21) Appl. No.: 18/813,122

(22) Filed: Aug. 23, 2024

Related U.S. Application Data
(60) Provisional application No. 63/538,863, filed on Sep. 18, 2023.

(30) Foreign Application Priority Data
Jul. 23, 2024 (CN) 202410989164.5

(51) Int. Cl. H05K 7/20

(52) U.S. Cl. CPC H05K 7/20272; H05K 7/20263; H05K 7/20781

(57) ABSTRACT

A coolant distribution device includes a housing, a heat exchanger, a first inlet port, a first outlet port, at least one pump assembly, and a first power connector. The housing has at least one opening. The heat exchanger and the at least one pump assembly are disposed in the housing. The first inlet port and the first outlet port are connected to the heat exchanger. A part of the at least one pump assembly passes through the at least one opening and is exposed from the housing. The at least one pump assembly is interconnected with the first inlet port and the heat exchanger. The first power connector is disposed on the housing and is configured to receive DC power.

### CROSS-REFERENCE TO RELATED PATENT APPLICATION

This application claims the benefit of priority to the U.S. Provisional Patent Application Ser. No. 63/538,863, filed on Sep. 18, 2023 which application is incorporated herein by reference in its entirety.

This application claims the benefit of priority to China Patent Application No. 202410989164.5, filed on Jul. 23, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a coolant distribution device, and more particularly to a coolant distribution device that directly receives direct current (DC) power for operation.

### BACKGROUND OF THE DISCLOSURE

A database center composed of multiple server racks containing multiple servers generally supplies coolant to each server arranged in each of the server racks through cooling distribution units (CDU) for cooling. The coolant absorbs the heat generated by the servers, and the coolant with heat is transferred to external circulation pipelines through CDU's delivery pipelines for heat dissipation. In other words, the CDU is an essential element in the liquid cooling process at the database center. The CDU can evenly distribute coolant or cooling water to various server racks, and regulate and control the coolant's flow to maintain the required temperature and flow rate of a system including multiple server racks.

Existing coolant distribution devices receive alternating current (AC) power. However, for servers produced according to the standard specifications of the Open Compute Project (OCP), each of the server racks utilizes centralized power distribution to transmit DC power to the servers (e.g., DC power supply) through busbars. Through the centralized power supply, power saving and reduction in the machine failure rate can be achieved. In summary, the existing coolant distribution devices cannot be adapted to new designs of the server racks.

Therefore, how to improve structural strength through the improvement of the coolant distribution device and overcome the above-mentioned inadequacy has become an important issue to be addressed in the relevant art.

### SUMMARY OF THE DISCLOSURE

In response to the above-referenced technical inadequacy, the present disclosure provides a coolant distribution device that directly receives DC power to operate.

In order to solve the above-mentioned problems, one of the technical aspects adopted by the present disclosure is to provide a coolant distribution device, which includes a housing, a heat exchanger, a first inlet port, a first outlet port, at least one pump assembly, and a first power connector. The housing has at least one opening. The heat exchanger and the at least one pump assembly are disposed in the housing. The first inlet port and the first outlet port are connected to the heat exchanger. A part of the at least one pump assembly passes through the at least one opening and is exposed from the housing. The at least one pump assembly is interconnected with the first inlet port and the heat exchanger. The first power connector is disposed on the housing and is configured to receive DC power.

In one of the possible or preferred embodiments, the at least one pump assembly is interconnected with the first inlet port and the heat exchanger through a guiding pipe.

In one of the possible or preferred embodiments, the at least one pump assembly includes at least one fluidic connector, and the at least one pump assembly is interconnected with the guiding pipe through the at least one fluidic connector.

In one of the possible or preferred embodiments, the at least one fluidic connector is a quick connector.

In one of the possible or preferred embodiments, the at least one pump assembly includes a second power connector and a power module, the second power connector is electrically connected to the power module, and the first power connector and the second power connector are electrically coupled to each other.

In one of the possible or preferred embodiments, the coolant distribution device further includes at least one guiding structure disposed on the housing, the at least one pump assembly includes a matching member, and the at least one pump assembly is disposed at the at least one guiding structure through the matching member.

In one of the possible or preferred embodiments, the at least one pump assembly includes a handle, and the handle is exposed from the housing.

In one of the possible or preferred embodiments, a quantity of the at least one pump assembly is two.

In one of the possible or preferred embodiments, the coolant distribution device further includes a controller disposed in the housing, the controller is coupled to the at least one pump assembly, and the controller is configured to transmit a control signal to the at least one pump assembly to adjust a flow pressure value of the at least one pump assembly.

In one of the possible or preferred embodiments, the controller includes a handle.

In one of the possible or preferred embodiments, the coolant distribution device further includes a liquid storage unit and a flow sensor, and the liquid storage unit and the flow sensor are disposed inside the housing and connected between the first inlet port and the at least one pump assembly.

In order to solve the above-mentioned problems, another one of the technical aspects adopted by the present disclosure is to provide a coolant distribution device, which includes a housing, a pump assembly, a heat exchanger, and a controller. The pump assembly is disposed in the housing. The pump assembly includes a power module, and the power module is configured to receive DC power. The heat exchanger is disposed in the housing and coupled to the pump assembly. The controller is disposed in the housing and coupled to the power module and the pump assembly. The controller is configured to adjust working parameters of the pump assembly based on a state of a heat source.

In one of the possible or preferred embodiments, the state includes a power or temperature of the heat source, and the working parameters include a flow pressure value or a rotational speed value of the pump assembly.

In one of the possible or preferred embodiments, the coolant distribution device further includes a detachable container, the detachable container is installed in the housing from at least one opening of the housing, and the pump assembly, the controller, or the power module are disposed in the detachable container.

In one of the possible or preferred embodiments, the housing includes a guiding structure, the detachable container includes a matching member that corresponds to the guiding structure, and the detachable container is configured to be assembled on the guiding structure through the matching member.

Therefore, in the coolant distribution device provided by the present disclosure, with the first power connector being electrically connected to copper busbars in the server racks, the coolant distribution device can directly receive DC power from the power supply units (PSUs) in a system including multiple servers. In other words, the coolant distribution device does not require an additional adapter to convert DC power to AC power, which reduces the internal components of the coolant distribution device and lowers manufacturing costs.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a first schematic view of a coolant distribution device according to the present disclosure;

FIG. 2 is a second schematic view of the coolant distribution device according to the present disclosure;

FIG. 3 is an internal schematic view of the coolant distribution device according to the present disclosure;

FIG. 4 is a schematic view of a controller being pulled out from the coolant distribution device according to the present disclosure;

FIG. 5 is a schematic view of a pump assembly being pulled out from the coolant distribution device according to the present disclosure; and

FIG. 6 is a schematic view of the pump assembly according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiment

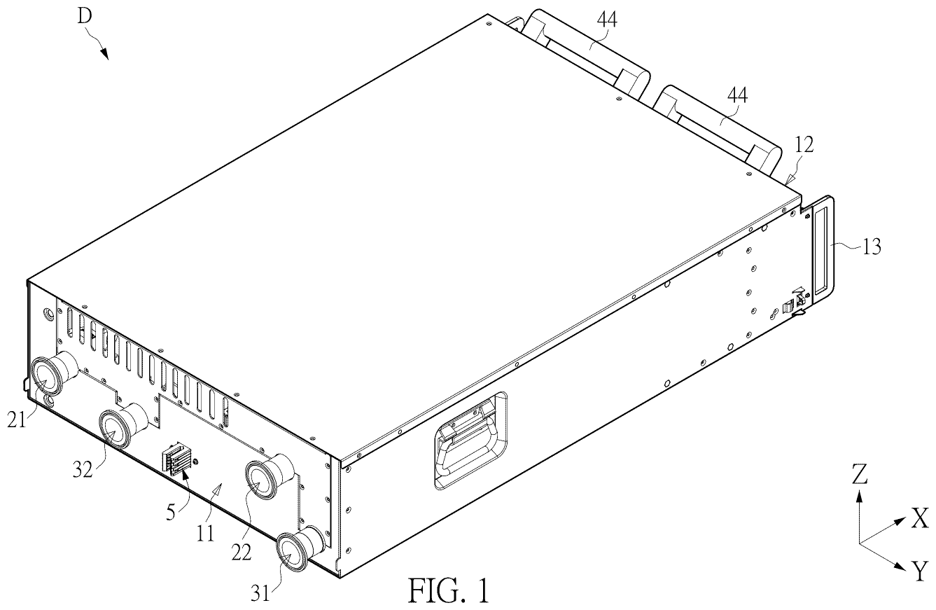

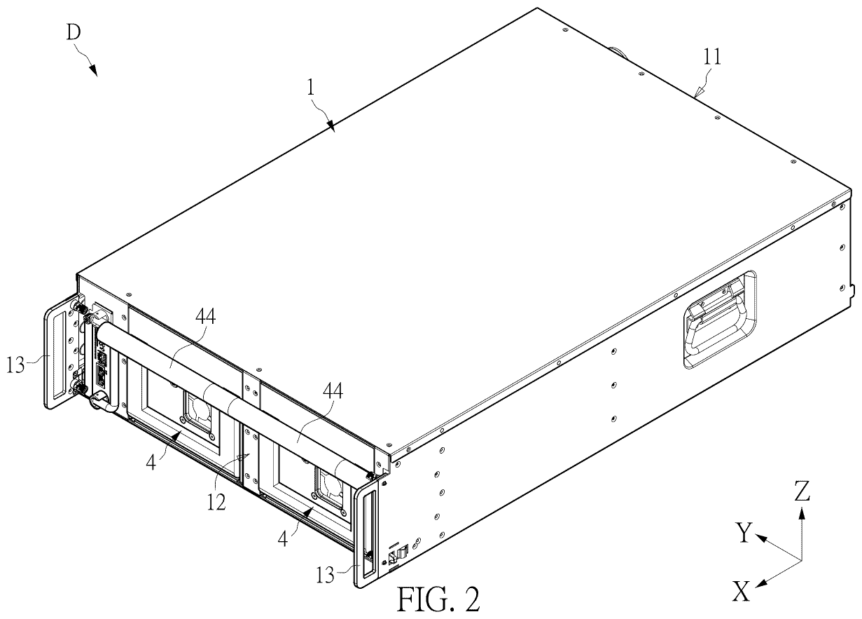

Reference is made to FIG. 1 and FIG. 2. FIG. 1 and FIG. 2 are schematic views of a coolant distribution device from different angles. The present disclosure provides a coolant distribution device D, which can be installed in a server rack (not shown in the figures). The coolant distribution device D includes a housing 1, a heat exchanger 3, a first inlet port 21, a first outlet port 22, at least one pump assembly 4, and a first power connector 5. The first inlet port 21 and the first outlet port 22 are disposed on the housing 1.

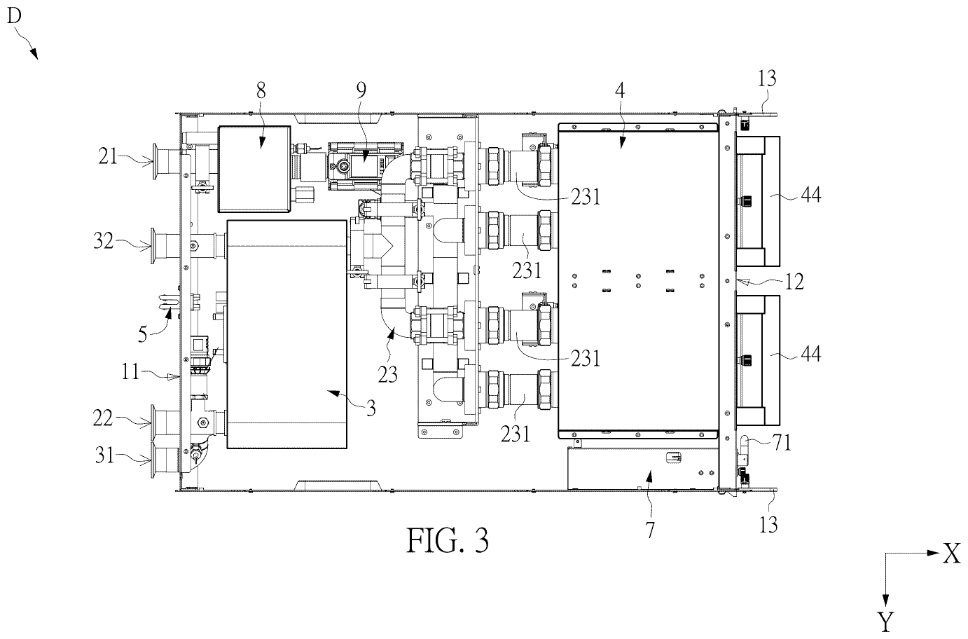

Reference is made to FIG. 1 to FIG. 3. FIG. 3 is an internal schematic view of the coolant distribution device according to the present disclosure. The housing 1 includes a first side cover 11 and a second side cover 12. The coolant distribution device D further includes a guiding pipe 23. The guiding pipe 23 is disposed in the housing 1. The first inlet port 21 and the first outlet port 22 are disposed on the first side cover 11 of the housing 1, and the guiding pipe 23 is connected to the first inlet port 21. The heat exchanger 3 and the at least one pump assembly 4 are disposed in the housing 1, and the first outlet port 22 is connected to the heat exchanger 3.

The coolant distribution device D further includes a second inlet port 31 and a second outlet port 32. The second inlet port 31 and the second outlet port 32 are connected to the heat exchanger 3. The heat exchanger 3 has two different kinds of fluids. One kind of fluid is water from a building, such as water supplied directly from a water tower or from the building's chiller. This kind of fluid is called a primary fluid (not shown in the figures), which enters through the second inlet port 31 of the coolant distribution device D and exits through the second outlet port 32 of the coolant distribution device D. The other kind of fluid is the target fluid for cooling, which is called a coolant or secondary fluid. The secondary fluid, or the coolant, enters through the first inlet port 21 and exits through the first outlet port 22. The secondary fluid is configured to absorb the heat generated by equipment such as servers in a database center. The two kinds of fluids are fed into different channels within the heat exchanger and flow close to a heat exchange surface through these channels to exchange heat. In this way, the temperature of the equipment can be maintained at a proper value by the coolant distribution device D.

The guiding pipe 23 is connected between the at least one pump assembly 4 and the first inlet port 21, and between the at least one pump assembly 4 and the heat exchanger 3. In other words, the at least one pump assembly 4 is interconnected with the first inlet port 21, and the at least one pump assembly 4 is interconnected with the heat exchanger 3 through the guiding pipe 23. Specifically, the coolant (i.e., the secondary fluid, not shown in the figures) absorbs the waste heat generated by the servers and enters the housing 1 through the first input port 21 and further flows into at least one pump assembly 4 through the guiding tube 23, thereby reducing the overall temperature of a system including multiple servers and achieving a heat dissipation effect. After that, the coolant with heat is transferred to the heat exchanger 3 through the guiding pipe 23 and performs heat exchange with the primary fluid in the heat exchanger 3.

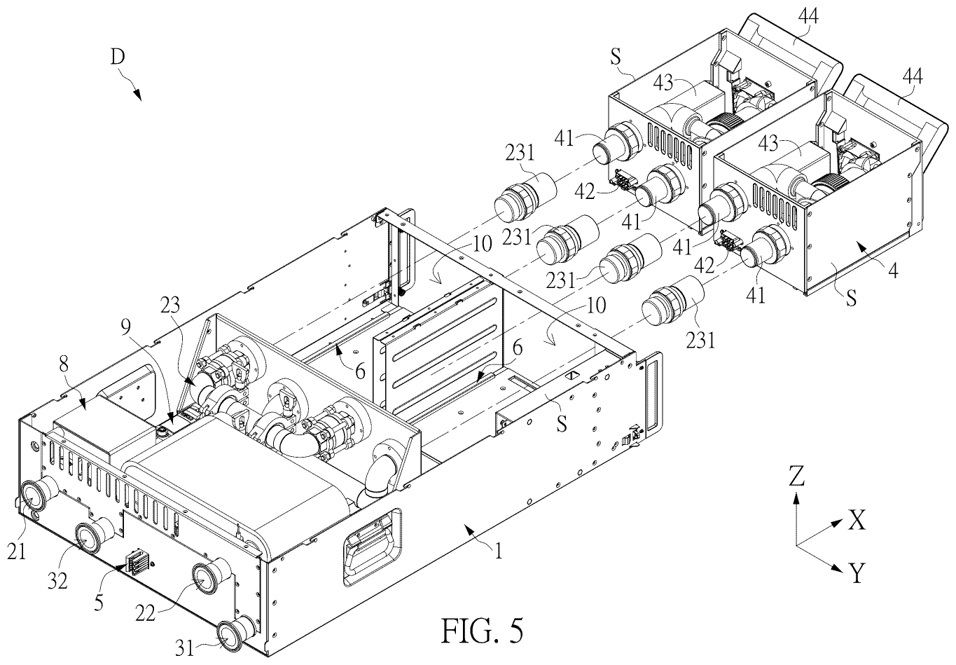

Reference is made to FIG. 5. FIG. 5 is a schematic view of a pump assembly being pulled out from the coolant distribution device according to the present disclosure. The at least one pump assembly 4 includes at least one fluidic connector 41, and the at least one fluidic connector 41 is interconnected with the guiding pipe 23 through the at least one fluidic connector 41. A quantity of the at least one pump assembly 4 is not limited in the present disclosure. For example, the coolant distribution device D provided by the present disclosure includes two pump assemblies 4. As shown in FIG. 5, each of the two pump assemblies 4 includes two fluidic connectors 41, and the guiding pipe 23 includes four fluidic connectors 231. The two pump assemblies 4 are interconnected with the guiding pipe 23 through the four fluidic connectors 41 being respectively connected to the four fluidic connectors 231.

For example, the four fluidic connectors 41 of the two pump assemblies 4 and the four fluidic connectors 231 of the guiding pipe 23 are both quick disconnect blind mate (QDBM) connectors. The four fluidic connectors 41 are male connectors, while the four fluidic connectors 231 are female connectors. Since each quick disconnect blind mate connector includes a waterproof ring (e.g., an O-ring) disposed within it, there is no water leakage when the male connector is disconnected from the female connector.

As shown in FIG. 5, the first power connector 5 is disposed on the housing 1, and the first power connector 5 is disposed on the first side cover 11 like the first inlet port 21 and the multiple first outlet ports 22. The first power connector 5 is electrically connected to the heat exchanger 3, the two pump assemblies 4, and a controller 7 mentioned below. Compared to the existing coolant distribution device powered by alternating current (AC) voltage, the coolant distribution device D of the present disclosure is powered by direct current (DC) voltage. Therefore, the first power connector 5 is a DC clip, which can be used to receive DC power. When the coolant distribution device D of the present disclosure is installed on the server racks, the coolant distribution device D is electrically connected to the copper busbars on the server racks through the first power connector 5, allowing the coolant distribution device D to directly receive DC power provided by the power supply units (PSUs) of the server racks.

Each of the two pump assemblies 4 further includes a second power connector 42 and a power module 43. The second power connector 42 is electrically connected to the power module 43. The first power connector 5 and the second power connector 42 are electrically coupled to each other. Therefore, the second power connector 42 can transmit the DC power from the first power connector 5 to the power module 43. That is, the pump assemblies 4 of the present disclosure are electrically coupled to the first power connector 5 through the second power connector 42, so as to receive the DC power provided by the system. Furthermore, in addition to the pump assemblies 4, the heat exchanger 3 of the coolant distribution device D and the controller 7 mentioned below are also powered by an external system (i.e., the server racks).

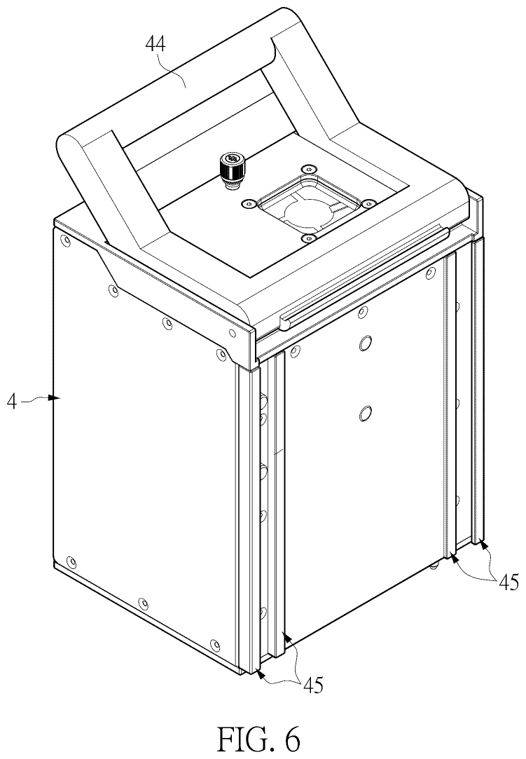

Reference is further made to FIG. 5 and FIG. 6. FIG. 6 is a schematic view of the pump assembly according to the present disclosure. Each of the two pump assemblies 4 further includes a handle 44. The second side cover 12 of the housing 1 has two openings 10. Parts of the two assemblies 4 are disposed on the two openings 10, respectively, and the two handles 44 are exposed from the housing 1. The housing 1 includes a guiding structure 6, which is disposed in the housing 1. Each of the two pump assemblies 4 includes a matching member 45 corresponding to the guiding structure 6. The pump assemblies 4 are assembled on the guiding structure 6 of the housing 1 through the matching members 45 and move relative to the housing 1.

The matching between the guiding structure 6 and the matching member 45 can be, for example, a groove that matches a convex portion, a track that matches a roller, or a support bar that matches a hook, and the present disclosure is not limited thereto. Moreover, the guiding structure can be disposed on a bottom plate or a side wall of the housing 1, and the present disclosure is not limited thereto. For example, in the present disclosure, the guiding structure 6 can be a guiding rail, and the matching member 45 can be a slider. Therefore, each of the two pump assemblies 4 is assembled on the guiding rail of the housing 1 through the slider and moves along the guiding rail.

Therefore, as shown in FIG. 5, each of the two pump assemblies 4 of the present disclosure is a pluggable component. Through the handle 44 of each of the two pump assemblies 4, which is exposed from the housing 1, and in conjunction with the design of the guiding structure 6 and the matching member 45, the user can grip the handle 44 and pull each of the two pump assemblies 4 out of the coolant distribution device D. Furthermore, when the user directly pulls out each of the two pump assemblies 4 for replacement or maintenance, the fluidic connector 41 and the second power connector 42 of each of the two pump assemblies 4 can be directly disconnected from the fluidic connector 231 and the first power connector 5. In other words, there is no need for complex disassembly steps, and the coolant distribution device D does not need to be shut down, which helps save costs in terms of labor and time.

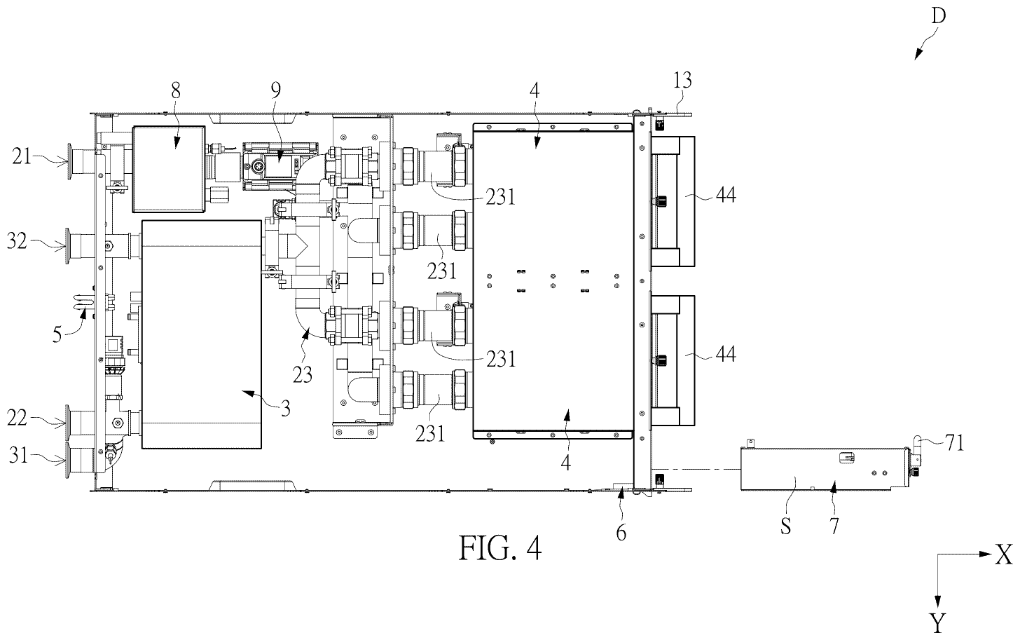

Reference is further made to FIG. 3 and FIG. 4. FIG. 4 is a schematic view of a controller being pulled out from the coolant distribution device according to the present disclosure. The coolant distribution device D further includes a controller 7, a liquid storage unit 8, and a flow sensor 9. The controller 7 is disposed in the housing 1 and coupled to the pump assemblies 4 and the flow sensor 9. The liquid storage unit 8 can be a water tank, which is disposed in the housing 1 and connected between the first inlet port 21 and the pump assemblies 4. The liquid storage unit 8 is configured to store the secondary fluid to ensure sufficient flow rate of the secondary fluid. The flow sensor 9 is configured to detect a flow rate of the secondary fluid. The controller 7 is configured to transmit a control signal to the pump assemblies 4 based on a state of a heat source, so as to adjust working parameters of the pump assemblies 4. For example, the heat source includes electronic components in the servers, the state of the heat source includes the power or temperature of these components, and the working parameters includes the flow pressure value or the rotational speed of the pump assemblies 4, as well as the flow rate of the coolant (i.e., the secondary fluid) flowing through the flow sensor 9. More specifically, the controller 7 can determine how to adjust the flow pressure value or the rotational speed of the pump assemblies 4 based on the power and temperature of the heat source.

Furthermore, the controller 7 is a pluggable component similar to the pump assemblies 4. The housing 1 includes another guiding structure 6 (e.g., a guiding rail) on which the controller 7 is installed. The second side cover 12 of the housing 1 has an opening corresponding to the controller 7, and the controller 7 includes a handle 71 and a matching member (e.g., a slider) that corresponds to the guiding structure 6. When the controller 7 is installed in the housing 1, the handle 71 is exposed from the housing 1. The user can grip the handle 71 and pull out the controller 7 from the inside of the coolant distribution device D. Furthermore, when the controller 7 is pulled out for replacement or maintenance, the coolant distribution device D does not need to be shut down. However, the pump assemblies 4 do not detect the control signal from the controller 7, and the working parameters of the pump assemblies 4 can be maintained at predetermined values.

Reference is further made to FIG. 4 and FIG. 5. In the coolant distribution device D provided by the present disclosure, the pump assemblies 4 and the controller 7 are both pluggable components. Therefore, the pump assemblies 4 and the controller 7 have a common structural design in terms of appearance, despite having different internal structures. Each of the pump assemblies 4 and the controller 7 is a detachable container S in appearance. The detachable container S is installed in the housing 1 from the opening 10 of the housing 1. The components of each of the pump assemblies 4 (e.g., a motor and a power module) or the component of the controller 7 (e.g. a motherboard) can be installed inside the detachable container S. The detachable container S includes an extraction portion such as the handles 44, 71. Moreover, the handles 44, 71 can be stowable handles or fixed handles. Alternatively, the extraction portion can be designed to be similar to a groove on a desk drawer, making it convenient for the user to grip and apply force.

### Beneficial Effects of the Embodiments

In the coolant distribution device D provided by the present disclosure, with the first power connector 5 being electrically connected to copper busbars in the server racks, the coolant distribution device can directly receive DC power from the PSUs in the system composed of multiple servers. In other words, the coolant distribution device does not require an additional adapter to convert DC power to alternating current (AC) power, which reduces the internal components of the coolant distribution device and lowers manufacturing costs.

Moreover, in the coolant distribution device D provided by the present disclosure, the pump assemblies 4 and the controller 7 are both pluggable components, which have the handles 44, 71 and the matching member 45 corresponding to the guide structure 6. When the pump assemblies 4 and the controller 7 are installed in the housing 1, the handles 44, 71 are exposed from the housing 1. The user can grip the handles 44, 71 and pull out the pump assemblies 4 and the controller 7 from the inside of the coolant distribution device D. There is no need for complex disassembly steps, and the coolant distribution device D does not need to be shut down, which helps save costs in terms of labor and time.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A coolant distribution device, comprising:
a housing having at least one opening;
a heat exchanger disposed in the housing;
a first inlet port;
a first outlet port, wherein the first inlet port and the first outlet port are connected to the heat exchanger;
at least one pump assembly disposed in the housing, wherein a part of the at least one pump assembly passes through the at least one opening and is exposed from the housing, and the at least one pump assembly is interconnected with the first inlet port and the heat exchanger; and
a first power connector disposed on the housing, wherein the first power connector is configured to receive direct current (DC) power.

2. The coolant distribution device according to claim 1, wherein the at least one pump assembly is interconnected with the first inlet port and the heat exchanger through a guiding pipe.

3. The coolant distribution device according to claim 2, wherein the at least one pump assembly includes at least one fluidic connector, and the at least one pump assembly is interconnected with the guiding pipe through the at least one fluidic connector.

4. The coolant distribution device according to claim 3, wherein the at least one fluidic connector is a quick connector.

5. The coolant distribution device according to claim 1, wherein the at least one pump assembly includes a second power connector and a power module, and the second power connector is electrically connected to the power module; and wherein the first power connector and the second power connector are electrically coupled to each other.

6. The coolant distribution device according to claim 1, further comprising at least one guiding structure disposed on the housing, wherein the at least one pump assembly includes a matching member, and the at least one pump assembly is disposed at the at least one guiding structure through the matching member.

7. The coolant distribution device according to claim 1, wherein the at least one pump assembly includes a handle, and the handle is exposed from the housing.

8. The coolant distribution device according to claim 1, wherein a quantity of the at least one pump assembly is two.

9. The coolant distribution device according to claim 1, further comprising a controller disposed in the housing, wherein the controller is coupled to the at least one pump assembly, and the controller is configured to transmit a control signal to the at least one pump assembly to adjust a flow pressure value of the at least one pump assembly.

10. The coolant distribution device according to claim 9, wherein the controller includes a handle.

11. The coolant distribution device according to claim 1, further comprising a liquid storage unit and a flow sensor, wherein the liquid storage unit and the flow sensor are disposed inside the housing and connected between the first inlet port and the at least one pump assembly.

12. A coolant distribution device, comprising:
a housing;
a pump assembly disposed in the housing, wherein the pump assembly includes a power module, and the power module is configured to receive direct current (DC) power;
a heat exchanger disposed in the housing and coupled to the pump assembly; and
a controller disposed in the housing and coupled to the power module and the pump assembly;
wherein the controller is configured to adjust working parameters of the pump assembly based on a state of a heat source.

13. The coolant distribution device according to claim 12, wherein the state includes the power or temperature of the heat source, and the working parameters include a flow pressure value or a rotational speed value of the pump assembly.

14. The coolant distribution device according to claim 12, further comprising a detachable container, wherein the detachable container is installed in the housing from at least one opening of the housing, and the pump assembly, the controller, or the power module are disposed in the detachable container.

15. The coolant distribution device according to claim 14, wherein the housing includes a guiding structure, the detachable container includes a matching member that corresponds to the guiding structure, and the detachable container is configured to be assembled on the guiding structure through the matching member.
